(19) United States
(12) Patent Application Publication
(10) Pub. No.: US 2014/0362539 A1
(43) Pub. Date: Dec. 11, 2014

(54) DISPLAY DEVICE

(71) Applicant: InnoLux Corporation, Miao-Li County (TW)

(72) Inventors: Wei-Shih HUANG, Miao-Li County (TW); Kun-Chih AI, Miao-Li County (TW); Shih-Yuan FENG, Miao-Li County (TW)

(73) Assignee: InnoLux Corporation, Miao-Li County (TW)

(21) Appl. No.: 14/283,410

(22) Filed: May 21, 2014

(30) Foreign Application Priority Data
Jun. 6, 2013 (TW) 102120103

(51) Int. Cl. H05K 1/14; H05K 1/02; H05K 7/20

(52) U.S. Cl. CPC H05K 1/142; H05K 7/20963; H05K 1/0201; H05K 2201/04
USPC 361/721; 361/752

(57) ABSTRACT

A display device comprises a display panel, a carrying member, a plurality of circuit connecting boards, a control circuit board and at least a front frame member. The carrying member carries the display panel. The circuit connecting boards are disposed adjacent to the carrying member and physically and electrically connected to the display panel. The shortest distance between the two adjacent circuit connecting boards is between 0.1 mm and 20 mm. The control circuit board is disposed adjacent to the carrying member and electrically connected to the circuit connecting boards, and electrically connected to the display panel through the circuit connecting boards. The front frame member is disposed at the outer edge of the carrying member and connected to the carrying member, and includes a turning portion and an extending portion. The thickness of the turning portion is greater than that of the extending portion.

### CROSS REFERENCE TO RELATED APPLICATIONS

This Non-provisional application claims priority under 35 U.S.C. §119(a) on Patent Application No(s). 102120103 filed in Taiwan, Republic of China on Jun. 6, 2013, the entire contents of which are hereby incorporated by reference.

### BACKGROUND OF THE INVENTION

1. Field of Invention

The invention relates to a display device.

2. Related Art

Flat display apparatuses, such as liquid crystal display (LCD) apparatuses or organic light emitting display apparatuses, having advantages such as low power consumption, less heat, light weight and non-radiation, are widely applied to various electronic products and gradually take the place of cathode ray tube (CRT) display apparatuses.

For the module design of a display panel, a high-resolution display panel usually accompanies more data lines and driver ICs as well as more circuit connecting boards and a larger control circuit board. Accordingly, the high-resolution display panel also generates more heat. Besides, the front frame of a display panel is a punched metal piece with an even thickness, and can be locked to the outer edge of the plastic frame of the display panel for example. However, because the more circuit connecting boards and control circuit boards take more space, the module of the prior art needs to be increased in thickness to provide more locking space for the front frame, but this will increase the thickness and weight of the display device and is unfavorable for the thinning tendency of the product. Besides, because the evenness of the front frame of the one-piece metal material is not sufficient for the LCD apparatus of the current wide-viewing-angle design (e.g. MVA, IPS, FFS), the display panel thereof will undergo some compression, pull or push, and thus cause the light leakage at the dark state (e.g. Pinch Mura).

Therefore, it is an important subject to provide a display device that is thinned and has higher structural strength and higher heat dissipation efficiency with the reduced light leakage due to compression (compressing light leakage).

### SUMMARY OF THE INVENTION

An objective of the invention is to provide a display device that has smaller size, higher structural strength and higher heat dissipation efficiency with the reduced compressing light leakage.

To achieve the above objective, a display device according to the invention comprises a display panel, a carrying member, a plurality of circuit connecting boards, a control circuit board and at least a front frame member. The carrying member carries the display panel. The circuit connecting boards are disposed adjacent to the carrying member and physically and electrically connected to the display panel. The shortest distance between the two adjacent circuit connecting boards is between 0.1 mm and 20 mm. The control circuit board is disposed adjacent to the carrying member and electrically connected to the circuit connecting boards, and electrically connected to the display panel through the circuit connecting boards. The front frame member is disposed at the outer edge of the carrying member and connected to the carrying member, and includes a turning portion and an extending portion. The thickness of the turning portion is greater than that of the extending portion.

In one embodiment, the shortest distance between the two adjacent circuit connecting boards is between 0.1 mm and 3 mm.

In one embodiment, the material of the front frame member includes aluminum, magnesium, liquid metal or alloy.

In one embodiment, the turning portion includes a long side and a length of the long side is between 2 mm and 50 mm.

In one embodiment, the front frame member covers the carrying member, the circuit connecting boards and the control circuit board, and covers a part of the display panel.

In one embodiment, the carrying member includes a turning portion, and the connection between the front frame member and the carrying member is adjacent to the turning portion.

In one embodiment, when the display device includes two or more front frame members, the front frame members are disposed on the outer edges of the display device and connected to the carrying member.

In one embodiment, the display device further includes a plurality of driving ICs. Each of the circuit connecting boards includes a surface facing the carrying member, and the driving ICs are disposed on the surfaces and correspond to the location of the turning portion.

In one embodiment, the display device further includes a heat conduction member, which is disposed between the circuit connecting boards and the front frame member and contacts the circuit connecting boards and the turning portion. The location of the heat conduction member corresponds to that of the driving IC.

In one embodiment, the front frame member further includes a microstructure, which is disposed on the turning portion and/or the extending portion.

As mentioned above, in the display device of the invention, the carrying member carries the display panel, the circuit connecting boards are disposed adjacent to the carrying member and physically and electrically connected to the display panel, and the shortest distance between two adjacent circuit connecting boards is between 0.1 mm and 20 mm. Besides, the control circuit board is electrically connected to the display panel through the circuit connecting boards, and the front frame member is disposed at the outer edge of the carrying member and connected to the carrying member. Moreover, the front frame member includes a turning portion and an extending portion, and the thickness of the turning portion is greater than that of the extending portion. Due to the special design of the front frame member of the invention, the display device can be made thinner and have higher structural strength and heat dissipation efficiency, and also the compressing light leakage can be reduced.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic diagram of a display device according to a preferred embodiment of the invention;

FIG. 1B is a partial exploded diagram of the display device in FIG. 1A;

FIG. 1C is a sectional diagram of the display device taken along the line A-A in FIG. 1A;

FIG. 1D is a schematic diagram of a front frame member in FIG. 1A; and

FIG. 2 is a partial exploded diagram schematically showing a display device according to another embodiment of the invention.

### DETAILED DESCRIPTION OF THE INVENTION

The present invention will be apparent from the following detailed description, which proceeds with reference to the accompanying drawings, wherein the same references relate to the same elements.

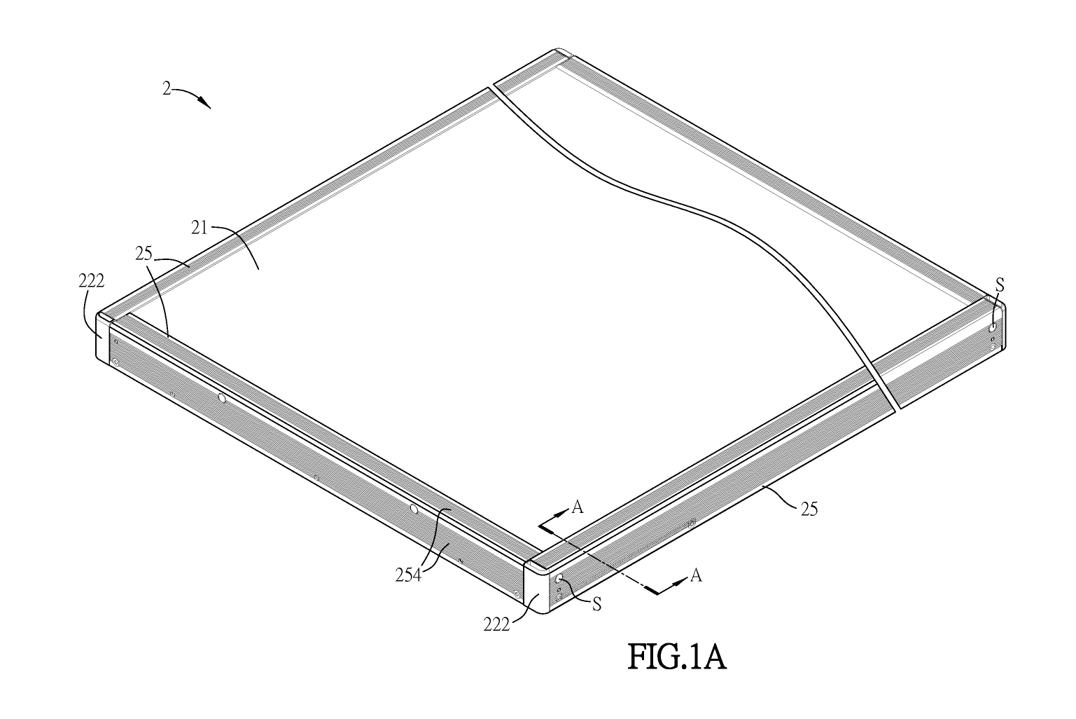

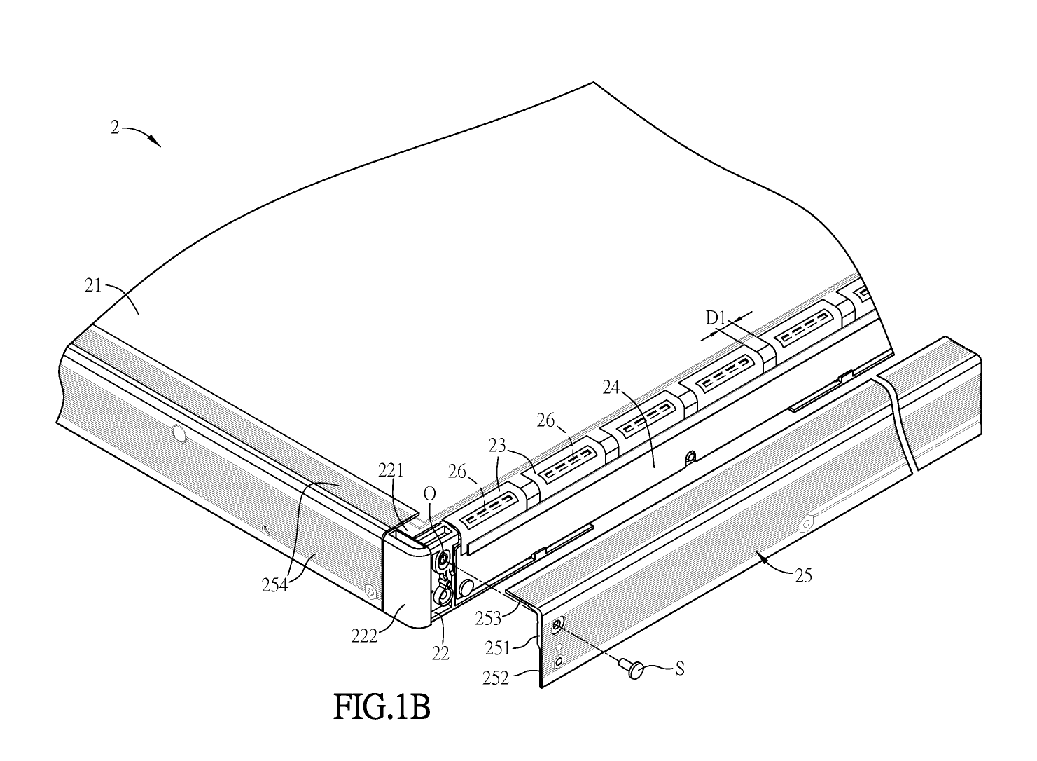

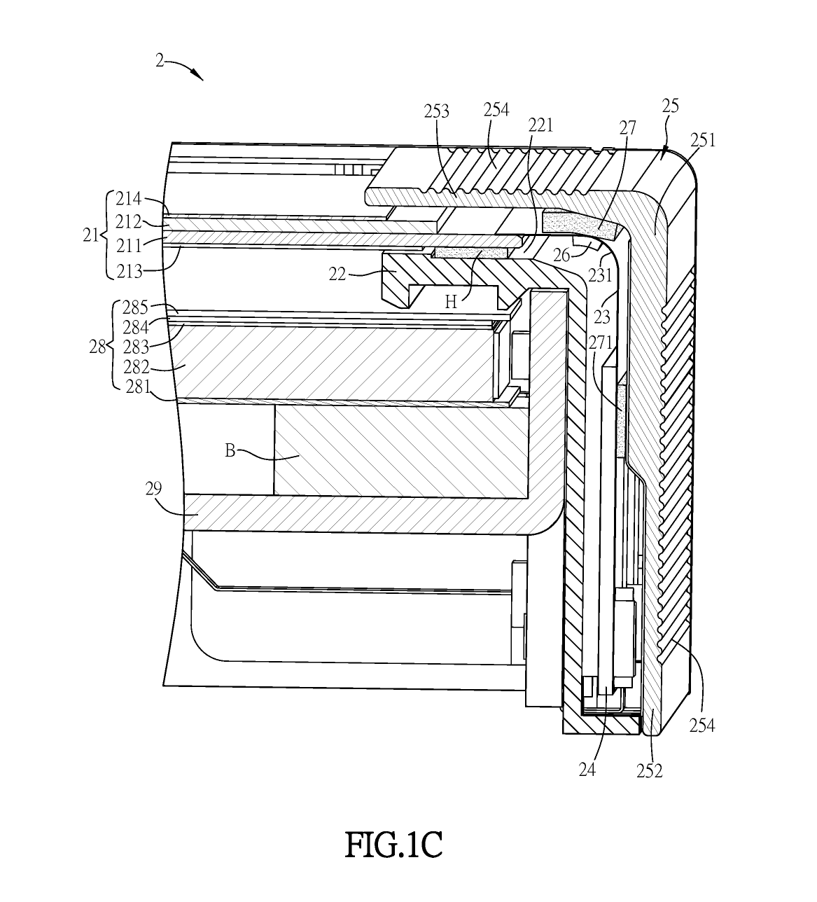

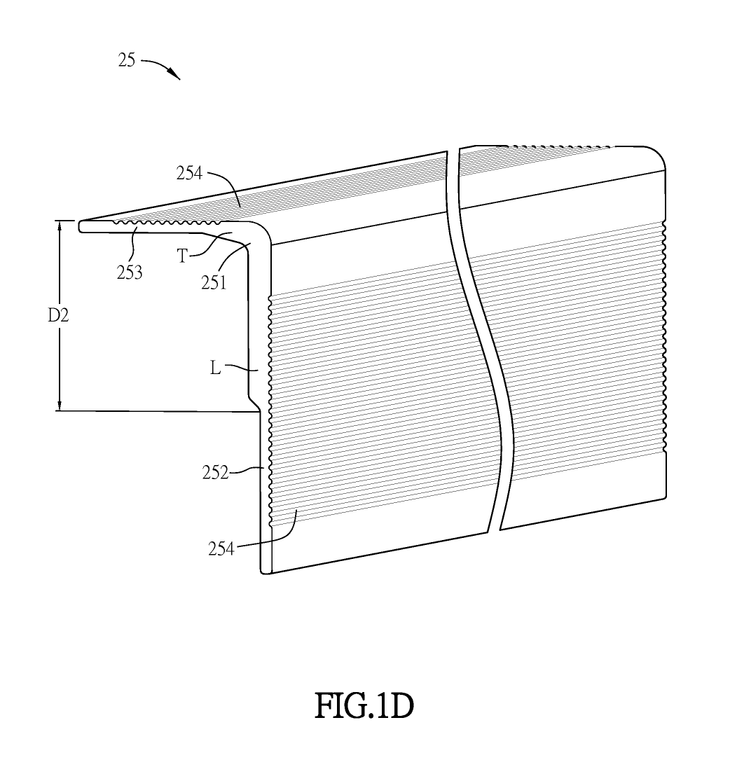

FIG. 1A is a schematic diagram of a display device 2 according to a preferred embodiment of the invention, FIG. 1B is a partial exploded diagram of the display device 2 in FIG. 1A, FIG. 1C is a sectional diagram of the display device 2 taken along the line A-A in FIG. 1A, and FIG. 1D is a schematic diagram of a front frame member 25 in FIG. 1A.

As shown in FIGS. 1A to 1D, the display device 2 includes a display panel 21, a carrying member 22, a plurality of circuit connecting boards 23, a control circuit board 24 and at least a front frame member 25.

The display panel 21 can be an LCD panel or an OLED panel. In this embodiment, the display panel 21, as shown in FIG. 1C, includes a first substrate 211 and a second substrate 212 which is disposed opposite to the first substrate 211. Herein, the size of the second substrate 212 is less than that of the first substrate 211. As an example, the first substrate 211 is a thin film transistor (TFT) substrate and the second substrate 212 is a color filter (CF) substrate. In other embodiments, the black matrix or color filter layer of the CF substrate can be removed to the TFT substrate, so that the first substrate 211 becomes a BOA (BM on array) substrate or a COA (color filter on array) substrate. The display panel 21 can further include a liquid crystal layer (not shown), which is disposed between the first substrate 211 and the second substrate 212, and the display panel 21 is thus an LCD panel.

The display panel 21 of this embodiment further includes a first polarization plate 213 and a second polarization plate 214. The first polarization plate 213 is disposed on the first substrate 211, and the second polarization plate 214 is disposed on the second substrate 212. Herein, the first polarization plate 213 is a lower polarization plate attached to the lower surface of the first substrate 211, and the second polarization plate 214 is an upper polarization plate attached to the upper surface of the second substrate 212. The size of the first polarization plate 213 is less than that of the first substrate 211, and the size of the second polarization plate 214 is less than that of the second substrate 212.

The carrying member 22 carries the display panel 21. Herein, the carrying member 22 has a carrying surface 221 disposed on the edge of the carrying member 22, and the carrying member 22 carries the display panel 21 through the carrying surface 221. In this embodiment, the carrying member 22 is a plastic frame having four sides. The display panel 21 is supported on the carrying surface 221 through a buffer material H (which is disposed between the carrying surface 221 and the first substrate 211) so as to be fixed to the carrying member 22. The buffer material H can be an adhesive material to stick the display panel 21 on the carrying member 22.

As shown in FIG. 1B, the circuit connecting boards 23 are disposed adjacent to the carrying member 22 and electrically connected to the display panel 21 by bonding. The circuit connecting board 23 is, for example but not limited to, a chip on film (COF). The circuit connecting boards 23 are physically and electrically connected to the upper surface of the first substrate 211 and bent to a side of the carrying member 22. The shortest distance Dl between the two adjacent circuit connecting boards 23 can be between 0.1 mm and 20 mm. Favorably, the said shortest distance D1 can be between 0.1 mm and 3 mm.

The control circuit board 24 is disposed adjacent to the carrying member 22, and physically and electrically connected to the circuit connection boards 23. The control circuit board 24 is electrically connected to the display panel 21 through the circuit connecting boards 23. Herein, the control circuit board 24 includes a driving circuit for driving the display panel 21, and is disposed to a side of the carrying member 22 to be electrically connected to the display panel 21 so as to drive the display panel 21 through the circuit connecting boards 23. The control circuit board 24 is, for example but not limited to, a printed circuit board (PCB), and is disposed adjacent to a side of the carrying member 22 by the bend of the circuit connecting boards 23.

At least a front frame member 25 is disposed at the outer edge of the carrying member 22 and connected to the carrying member 22. As shown in FIG. 1B, the front frame member 25 covers the carrying member 22, the circuit connecting boards 23 and the control circuit board 24, and is extended to cover a part of the display panel 21, becoming a part of the appearance of the display device 2. The front frame member 25 can be a metal piece and an assembled piece (i.e. not an integrally formed one-piece). The material of the front frame member 25 is, for example but not limited to, aluminum, magnesium, liquid metal or alloy (e.g. titanium alloy), or other materials of high thermal conductivity. Moreover, the front frame member 25 can be formed by aluminum extrusion, casting or injection molding for example. The front frame member 25 and the carrying member 22 can be connected to each other by locking, wedging or their combination for example.

In this embodiment, there are four front frame members 25 formed by aluminum extrusion. The front frame members 25 are disposed on the outer edges of the display device 2 and connected to the carrying member 22, becoming a part of the appearance of the display device 2. Because the aluminum extrusion material (e.g. AL 6063-T5) has a higher thermal conductivity (value-K) than the conventional material of the front frame member (such as steel material) and has less weight and higher structural strength, the display device 2 can have higher structural strength and heat dissipation efficiency when the aluminum-extruded front frame member 25 is used. Besides, in comparison with the prior art, the aluminum-extruded front frame member 25 has higher structural strength and greater evenness, so the compressing light leakage (such as Pinch Mura) problem of the display device 2 can be reduced.

As shown in FIGS. 1A and 1B, each of the front frame members 25 is connected to the carrying member 22 by the two ends of the front frame member 25, as an embodiment. Herein, the carrying member 22 includes four turning portions. At least a screws S is screwed into a screw hole O adjacent to the turning portion 222 through the front frame member 25 and the carrying member 22 (or through a rear frame member 29 as shown in FIG. 1C), so that the front frame members 25 are connected to the four sides of the carrying member 22, respectively. Besides, when the front frame members 25 are connected to the carrying member 22, the turning portions 222 of the carrying member 22 are exposed, making the display device 2 a more beautiful appearance.

As shown in FIG. 1D, the front frame member 25 includes a turning portion 251 and two extending portions 252 and 253, and the extending portions 252 and 253 are connected to two ends of the turning portion 251, respectively. The thickness of the turning portion 251 is greater than that of the extending portions 252 and 253, and therefore the entire front frame member 25 has an uneven thickness. Herein, the two extending portions 252 and 253 are substantially perpendicular to the turning portion 251. To be noted, the turning portion 251 does not just include the turnings of the extending portions 252 and 253 facing each other, but also includes the portion adjacent to the turning portion as long as it is between the extending portions 252 and 253 and has greater thickness. Herein for example, the turning portion 251 includes a long side L and a short side T, and a length D2 of the long side L is between 2 mm and 50 mm. Because the front frame member 25 is designed with different thicknesses (the thickness of the turning portion 251 is greater than that of the extending portions 252 and 253) and the front frame members 25 is connected to the carrying member 22 by the two ends of the front frame member 25, the locking space as shown in FIG. 1 is no more necessary for the carrying member 22 of the invention, in comparison with the prior art. Besides, the heights of the carrying member 22 and front frame member 25 can be reduced in this embodiment, and therefore the display device 2 can be made thinner.

The front frame member 25 further includes a microstructure 254, which is disposed on the turning portion 251 and/or the extending portion 252 or 253. Herein for example, the microstructure 254 includes many wavy grooves located on the turning portion 251 and the extending portions 252 and 253. The design of the wavy grooves not only provides a better appearance and higher strength but also increases the heat dissipation area of the front frame member 25. In this embodiment, the design of the microstructure 254 brings about 8% increment of the heat dissipation area. Thereby, the heat convection and heat radiation can be enhanced and the heat dissipation efficiency of the display device 2 can be thus increased. Besides, the wavy grooves can reduce the damage caused by the external collision.

As shown in FIGS. 1B and 1C, the display device 2 further includes a plurality of driving ICs 26. Each of the circuit connecting boards 23 includes a surface 231 facing the carrying member 22, and the driving ICs 26 are disposed on the surfaces 231 and correspond to the location of the turning portion 251. The driving IC 26 is a data driver of the display device 2 for example. For the driving IC 26 as a main heat source, the display device 2 can further include a heat conduction member 27, e.g. a thermal pad, which is disposed between the circuit connecting boards 23 and the front frame member 25 and contacts the circuit connecting boards 23 and the turning portion 251. The location of the heat conduction member 27 corresponds to that of the driving IC 26. Thereby, the heat generated by the driving ICs 26 can be transferred to the outside through the circuit connecting boards 23 and the heat conduction member 27 and then through the front frame member 25 of high thermal conductivity, and therefore the heat dissipation efficiency of the display device 2 can be enhanced further. Herein, because the turning portion 251 of the front frame member 25 is thicker, the heat conduction member 27 can be thinner so as to be directly attached to the turning portion 251. In comparison with the prior art, some material (such as a thermal plate or fastening screws) can be saved in this embodiment and the thinned heat conduction member 27 can make higher heat conduction efficiency.

Moreover, the display device 2 can further include another heat conduction member 271, which is disposed between the control circuit board 24 and the front frame member 25 and contacts the control circuit board 24 and the turning portion 251. Thereby, the heat generated by the control circuit board 24 can be transferred to the outside by the front frame member 25 through the heat conduction member 271 and the turning portion 251.

The display device 2 further includes a backlight module 28 and a rear frame member 29. The backlight module 28 is disposed opposite to the display panel 21. The backlight module 28 can emit the light to the display panel 21, and the display panel 21 can display images accordingly. In this embodiment, the backlight module 28 includes a reflective plate 281, a light guiding plate 282 and a plurality of optical films 283, 284, 285. The optical films 283˜285 can include a light convergence film or diffusion film for example. Since the backlight module 28 can be embodied in a conventional way and comprehended by those skilled in the art, it is not described here for conciseness. The rear frame member 29 is connected to the inside of the carrying member 22, and the backlight module 28 is disposed in the rear frame member 29 through another buffer material B.

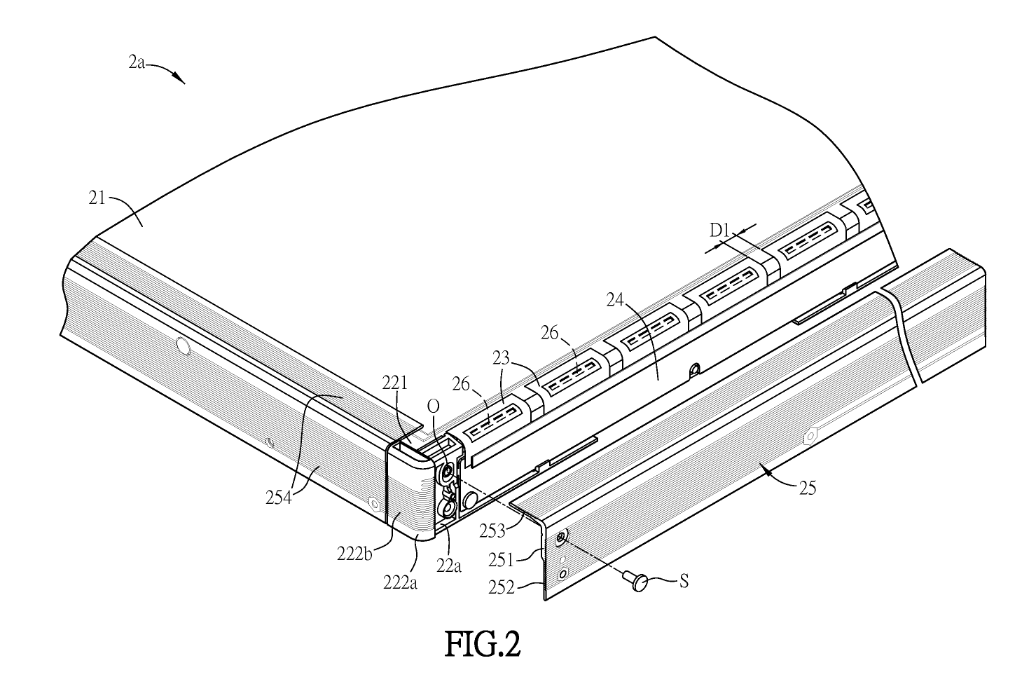

FIG. 2 is a partial exploded diagram schematically showing a display device 2a according to another embodiment of the invention.

Mainly different from the display device 2 in FIG. 1B, the turning portion 222a of the display device 2a includes a microstructure 222b, and the microstructure 222b also includes wavy grooves (with the pitch less than 1 mm, e.g. 0.1 mm). The wavy grooves of the microstructure 222b of the turning portion 222a are even with those of the microstructure 254 of the front frame member 25. In other words, the extensions of the wavy grooves of the microstructure 254 just follow the wavy grooves of the microstructure 222b. Thereby, when the front frame member 25 and the carrying member 22a are assembled, it can be ascertained that the top surfaces of the front frame member 25 and carrying member 22a are on the same level by making sure the wavy grooves of the microstructures 254 and 222b are even with each other. Accordingly, the assembly can be achieved better.

Other technical features of the display device 2a can be comprehended by referring to the display device 2, and therefore they are not described here for conciseness.

To sum up, in the display device of the invention, the carrying member carries the display panel, the circuit connecting boards are disposed adjacent to the carrying member and physically and electrically connected to the display panel, and the shortest distance between two adjacent circuit connecting boards is between 0.1 mm and 20 mm. Besides, the control circuit board is electrically connected to the display panel through the circuit connecting boards, and the front frame member is disposed at the outer edge of the carrying member and connected to the carrying member. Moreover, the front frame member includes a turning portion and an extending portion, and the thickness of the turning portion is greater than that of the extending portion. Due to the special design of the front frame member of the invention, the display device can be made thinner and have higher structural strength and heat dissipation efficiency, and also the compressing light leakage can be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display device comprising:
a display panel;
a carrying member carrying the display panel;
a plurality of circuit connecting boards disposed adjacent to the carrying member and physically and electrically connected to the display panel, wherein the shortest distance between the two adjacent circuit connecting boards is between 0.1 mm and 20 mm;
a control circuit board disposed adjacent to the carrying member and electrically connected to the circuit connecting boards, and electrically connected to the display panel through the circuit connecting boards; and
at least a front frame member disposed at the outer edge of the carrying member and connected to the carrying member, and including a turning portion and an extending portion, wherein the thickness of the turning portion is greater than that of the extending portion.

2. The display device as recited in claim 1, wherein the shortest distance between the two adjacent circuit connecting boards is between 0.1 mm and 3 mm.

3. The display device as recited in claim 1, wherein the material of the front frame member includes aluminum, magnesium, liquid metal or alloy.

4. The display device as recited in claim 1, wherein the turning portion includes a long side and a length of the long side is between 2 mm and 50 mm.

5. The display device as recited in claim 1, wherein the front frame member covers the carrying member, the circuit connecting boards and the control circuit board, and covers a part of the display panel.

6. The display device as recited in claim 1, wherein the carrying member includes a turning portion, and the connection between the front frame member and the carrying member is adjacent to the turning portion.

7. The display device as recited in claim 1, wherein when the display device includes two or more front frame members, the front frame members are disposed on the outer edges of the display device and connected to the carrying member.

8. The display device as recited in claim 1, further comprising:
a plurality of driving ICs, wherein each of the circuit connecting boards includes a surface facing the carrying member, and the driving ICs are disposed on the surfaces and correspond to the location of the turning portion.

9. The display device as recited in claim 8, further comprising:
a heat conduction member disposed between the circuit connecting boards and the front frame member and contacting the circuit connecting boards and the turning portion, wherein the location of the heat conduction member corresponds to that of the driving IC.

10. The display device as recited in claim 1, wherein the front frame member further includes a microstructure, which is disposed on the turning portion and/or the extending portion.
